(19) United States
(12) Patent Application Publication
(10) Pub. No.: US 2015/0037923 A1
(43) Pub. Date: Feb. 5, 2015

(54) METHODS TO SELECTIVELY TREAT PORTIONS OF A SURFACE USING A SELF-REGISTERING MASK

(71) Applicant: 1366 TECHNOLOGIES, INC., BEDFORD, MA (US)

(72) Inventors: Vladimir S. Tarasov, Somerville, MA (US); Ali Ersen, Chestnut Hill, MA (US); ERIC Stern, Cambridge, MA (US); Jason M. Criscione, Billerica, MA (US); Emanuel M. Sachs, Newton, MA (US)

(73) Assignee: 1366 TECHNOLOGIES, INC., BEDFORD, MA (US)

(21) Appl. No.: 14/370,321

(22) PCT Filed: Jan. 6, 2013
(86) PCT No.: PCT/US13/20435

§ 371 Date: Jul. 2, 2014

Related U.S. Application Data
(60) Provisional application No. 61/583,706, filed on Jan. 6, 2012.

(51) Int. Cl. H01L 31/0236; H01L 31/0248

(52) U.S. Cl. CPC H01L 31/02363; H01L 31/0248
USPC 438/71

(57) ABSTRACT

Processes increase light absorption into silicon wafers by selectively changing the reflective properties of the bottom portions of light trapping cavity features. Modification of light trapping features includes: deepening the bottom portion, increasing the curvature of the bottom portion, and roughening the bottom portion, all accomplished through etching. Modification may also be by the selective addition of material at the bottom of cavity features. Different types of features in the same wafers may be treated differently. Some may receive a treatment that improves light trapping while another is deliberately excluded from such treatment. Some may be deepened, some roughened, some both. No alignment is needed to achieve this selectively. The masking step achieves self-alignment to previously created light trapping features due to softening and deformation in place.

### RELATED DOCUMENTS

The benefit of U.S. Provisional Application No. 61/583,706 filed Jan. 6, 2012, entitled, Methods of Using a Thermoplastic Resist for Multi-Step Etching of Mono- and Multi-Crystalline Silicon Wafers, is hereby claimed, and the entire disclosure of which is hereby incorporated fully herein, by reference.

To maximize silicon solar cell efficiencies it is critical to texture the silicon surface to reduce reflectivity. This is most commonly achieved with wet chemical etchants in batch or in-line processes. Monocrystalline silicon wafers are etched with alkaline etchants that take advantage of their crystalline structure to yield pyramids that are ideal for limiting reflectivity. Multicrystalline wafers have no such crystalline structure to exploit and, in turn, are traditionally etched with acid etchants. These can use the saw-damaged wafer surface to create random texture or a patterned mask to create a repeating texture. The lowest reflectivities have been reported with honeycomb-array repeated textures.

Certain processing schemes and architecture are disclosed using a patterned mask to create texture, in Patent Cooperation Treaty Application No: PCT/US2008/002058, entitled, SOLAR CELL WITH TEXTURED SURFACES, Filed: Feb. 15, 2008, in the names of Emanuel M. Sachs and James F. Bredt and The Massachusetts Institute of Technology, designating the United States of America, the National Phase of which is U.S. patent application Ser. No. 12/526,439, issued as U.S. Pat. No. 8,257,998 on Sep. 4, 2012, and also claiming priority to two provisional United States applications, No. U.S. 60/901,511, filed Feb. 15, 2007, and No. U.S. 61/011,933, filed Jan. 23, 2008. All of the PCT application, the U.S. patent, patent application, and the two US provisional applications are hereby incorporated fully herein by reference. The technology disclosed in these applications is referred to herein collectively as Self Aligned Cell (SAC) technology.

Certain additional processing methods and apparatus are disclosed in Patent Cooperation Treaty Application No. PCT/US2009/002423, entitled WEDGE IMPRINT PATTERNING OF IRREGULAR SURFACE, filed Apr. 17, 2009, in the names of Benjamin F. Polito, Holly G. Gates and Emanuel M. Sachs, and the Massachusetts Institute of Technology and 1366 Industries Inc., designating the United States of America, the National Phase of which is U.S. patent application Ser. No. 12/937,810, and also claiming priority to two provisional United States applications, No. U.S. 61/124,608, filed Apr. 18, 2008, and No. U.S. 61/201,595, filed Dec. 12, 2008. All of the PCT application, the U.S. patent application, and the two US provisional applications are hereby incorporated fully herein by reference. The technology disclosed in the applications mentioned in this paragraph is referred to herein collectively as wedge imprint technology or wedging technology, although in some instances protrusions having shapes other than wedges may be used. The related applications are referred to below as the Wedging applications.

Certain additional processing methods and apparatus are disclosed in Patent Cooperation Treaty Application No. PCT/US2012/056769, entitled TECHNIQUES FOR IMPROVED IMPRINTING OF SOFT MATERIAL ON SUBSTRATE USING STAMP INCLUDING UNDERFILLING TO LEAVE A GAP AND PULSING STAMP, filed Sep. 22, 2012, in the names of Emanuel M. Sachs, and 1366 Industries Inc., designating the United States of America, claiming priority to provisional United States applications, No. U.S. 61/538,489, filed Sep. 22, 2011. All of the PCT application, and the provisional application mentioned in this paragraph are hereby incorporated fully herein by reference. The technology disclosed in the applications mentioned in this paragraph is referred to herein as gap technology and stamp pulsing technology.

Due to the presence of a wide variety of grain orientations in multicrystalline silicon wafers, isotropic etching is most commonly employed to establish features in the surface of wafers, for instance to improve light trapping. As is known to those skilled in the art of isotropic etching, the feature geometries are limited to shapes that are approximately hemispheres. FIGS. 8A, 8B, 8C and 8D show, schematically, four instances of a light ray, normally incident on a substantially hemispherical pit 803 in a silicon wafer 800, having a top surface 801, encapsulated under glass 811, having a top surface 802. The images are cross-sections through the center of the hemispherical pit 803. The encapsulation in a module typically also has a layer of polymer between the wafer and the glass. However, this polymer has the same index of refraction as the glass and so, the interface between the polymer and glass has no influence on the path of a light ray and is not shown in FIG. 100A. For clarity, only a single pit 803 is shown, whereas there would typically be a field of pits in a wafer. In FIG. 8A, an incident ray 804 hits the pit 803 at a point 805, which is closer to the edge E of the pit than to its center C. The majority of the incident ray enters the silicon (not shown). However, a portion is reflected as ray 806, shown in dashed line. This reflected ray strikes the same pit at point 807, a portion of which is then absorbed adjacent that point 807, and therefore more of the energy has a chance to be absorbed.

In FIG. 8B, a ray 804′ is incident on the pit at a point 808, which is closer to the center C of the pit, as compared to the point 5 shown in the case of FIG. 8A. In this case, the reflected ray does not hit the wall of the pit 803 again, but rather escapes the pit as ray 809. However, this ray is traveling toward the glass surface 802 at an angle of 56 degrees from the normal. At this angle, the ray undergoes total internal reflection (TIR) when it hits the surface 802 of the glass at point 810 and comes back down to hit the wafer 800 at another spot (not shown) on its surface 801. Once again, at least two intersections of the incident and reflected rays with the wafer 800 are guaranteed, providing for relatively high absorption. FIG. 8C shows a similar case where the angle of the reflected ray 812 with respect to the vertical is 44 degrees, which also results in two intersections with the wafer 800.

However, in FIG. 8D, where the angle of the reflected ray 814 with respect to the vertical is 40 degrees, the reflected ray does not undergo total internal reflection, but escapes through the glass 811, from the module. The absorption of the incident ray will therefore generally be lower than in the other cases. For most glasses (index of refraction of approximately 1.5), the critical angle of the reflected ray with respect to the vertical larger than which TIR takes place and less than which it does not, is 42 degrees.

If the pit were a perfect hemisphere, this same escape would transpire for all rays that are as close or closer to the center than is the ray shown at FIG. 8D. The actual degree of escape depends to some extent on the local irregularities in the surface that tilt one way or another. But, generally, with random variations in that aspect, those rays that strike closer to the center have a larger chance of escaping than do those that strike further from the center.

Thus, the portion of a hemispherical pit 803 relatively nearer its bottom C presents surfaces that are too close to horizontal to reflect rays at steep enough angles to guarantee at least a second impact on the wafer 800.

Surface morphologies that improve the absorption and reduce the reflectivity of incident light on the silicon wafer are desired.

These and other objects and aspects of inventions disclosed herein will be better understood with reference to the Figures of the Drawing, of which:

### BRIEF DESCRIPTION OF THE FIGURES OF THE DRAWING

FIG. 1 shows, schematically, a stamp used for wedging (prior art);

FIG. 2 shows, schematically, the stamp of FIG. 1 and a substrate coated with an etch resist, to be patterned by the stamp to form a mask (prior art);

FIG. 3 shows, schematically, the stamp and substrate of FIG. 2, with tips of protrusions of the stamp just contacting the resist (prior art);

FIG. 4 shows schematically a stamp and a substrate operating in a filled mode, with the protrusions of the stamp deformed and pressed against the substrate, and with resist substantially filling the space between the substrate and the body of the stamp (prior art);

FIG. 5 shows, schematically, a stamp and substrate, with a patterned resist coating the substrate after wedging with the stamp (prior art);

FIG. 6 shows, schematically, a substrate after etching, with a patterned resist mask as shown in FIG. 5 (prior art);

FIG. 7 shows, schematically, a stamp and substrate similar to that of FIG. 3, after wedging according to a method that leaves a gap between the top of the resist surface and the underside of the stamp, when the protrusions are deformed to the fullest extent of deformation, with the components separated, revealing patterned, peaked resist;

FIG. 8A shows, schematically, a cross-sectional view through a pit in a encapsulated silicon solar module, showing a light ray that hits a wall of the pit, reflects and hits another portion of the wall of the pit, thereby encountering the silicon at least twice;

FIG. 8B shows, schematically, a light ray striking the wall of a pit, as in FIG. 8A, but closer to the center C of the bottom of the pit, which reflects, escapes the pit hits the glass surface, and undergoes total internal reflection (TIR) and then comes back down to hit the wafer at another spot;

FIG. 8C shows a similar case to that shown in FIG. 8B, but where the ray strikes the pit even closer to its center, C, is reflected at an angle that is even closer to vertical (and the incoming ray), yet also strikes the glass at such an angle as to undergo TIR;

FIG. 8D shows a case where the ray strikes the pit even closer yet to its center, C, is reflected at an angle that is still closer to vertical (and the incoming ray) than any of the preceding cases, and escapes through the glass, from the module;

FIG. 9 shows, schematically, two different rays, which strike a pit having a fine-grain topography, one of which rays escapes the pit, the other of which strikes another wall of the pit for a second instance of absorption;

FIG. 10A shows, schematically, a wafer that has been etched through a resist mask, some of which has been removed from the figure to show the top surface of the etched wafer, which has been etched to a significant degree, so that no flat surface of the original wafer remains;

FIG. 10B shows, schematically, a wafer that has been etched through a resist mask, again with a portion of the mask shown removed, which wafer has been etched to a lesser degree than that shown in FIG. 10A, so that flat surface of the original wafer remain in six hexagonally arranged, small, approximately triangular pillars around each pit;

FIG. 10C shows, schematically, a wafer that has been etched through a resist mask, again with a portion of the mask shown removed, which wafer has been etched to an even lesser degree than that shown in FIG. 10B, so that a flat surface of the original wafer remains in the six hexagonally arranged, small, approximately triangular pillars around each pit, and also a substantially circular rim;

FIG. 11A shows, schematically, a wafer such as is shown in FIG. 10B, with a moderate degree of etching, after the resist mask has been softened and allowed to drape against the walls of the pits, to a degree that leaves open spaces at the bottoms of substantially all of the pits;

FIG. 11B shows, schematically, a wafer such as is shown in FIG. 10B, after the resist mask has been softened and allowed to drape against the walls of the pits, to a more significant degree than that shown in FIG. 11A, which leaves open spaces at the bottoms of the pits, which open spaces are smaller than those shown in FIG. 11A;

FIG. 11C shows, schematically, a wafer such as is shown in FIG. 10B, after the resist mask has been softened and allowed to drape against the walls of the pits, to a still more significant degree than that shown in FIG. 11B, which leaves open spaces at the bottoms of the pits, which open spaces are even smaller than those shown in FIG. 11B;

FIG. 12 shows schematically, a wafer that has been etched a first time, with a covering resist mask, such as shown in FIG. 10B, the resist of which was then allowed to soften and drape the walls of the pits, such as shown in FIG. 11B, with a subsequent additional etch, to deepen the pits, to result in a plurality of compound pits;

FIG. 13 shows schematically, a wafer that has been etched a first time, with a covering resist, such as shown in FIG. 10B, the resist of which was then allowed to soften and drape the walls of the pits, such as shown in FIG. 11B, with a subsequent additional etch, or other surface treatment, to roughen the bottoms only of the pits, to result in a plurality of rough bottom pits, or, alternatively, pits with some other condition at their bottoms;

FIG. 14 shows, graphically, the reflectivity vs. wavelength, for solar material of different surface treatments, including flat, simple pits; compound pits, and rough-bottom pits;

FIG. 15A shows, schematically, a wafer that has been treated similarly to that shown in FIG. 12, but with a mask that also produces grooves, rather than only pits; and

FIG. 15B shows, schematically, wafer prepared such as shown in FIG. 15A, the resist of which was then allowed to soften and drape the walls of the pits, such as shown in FIG. 11B, and the groove, with a subsequent additional etch, to deepen the pits and the groove, to result in a plurality of compound pits and a compound groove.

### SUMMARY

Inventions disclosed herein entail processes designed to increase light absorption into silicon wafers by selectively changing the reflective properties of the bottom portions of light trapping features.

In certain aspects, topography is created at the base of substantially hemispherical pits, which provides for relatively larger angle reflections, which results in at least a second impact with the silicon surface of the wafer. In other aspects, a secondary topography is created at the base of pits or features by an etching or other procedure, which secondary topography provides for relatively larger angle reflections than the primary topography, which results in at least a second impact with the silicon surface of the wafer. In yet a further aspect, topography designed to decrease reflectivity of incident light on a surface, is selectively located in the bottom of a pit, while the remainder of the pit is relatively smooth, or, unchanged.

Suitable modification of these light trapping features includes, but is not limited to: making the bottom portion deeper, increasing the curvature of the bottom portion, and increasing the roughness of the bottom portion, all accomplished through an etching step. Suitable modification may also be by the selective addition of material at the bottom of features. Different types of features in the same wafers may be treated differently. For example, some features may receive a treatment that improves light trapping while another type of feature is deliberately excluded from such treatment. Importantly, there is no alignment needed to achieve this selectivity, but rather, the masking step achieves self-alignment to previously created light trapping features. In a typical embodiment, such self-alignment, or registration, takes place over a field of tens of millions, even a hundred million pits.

### DETAILED DESCRIPTION

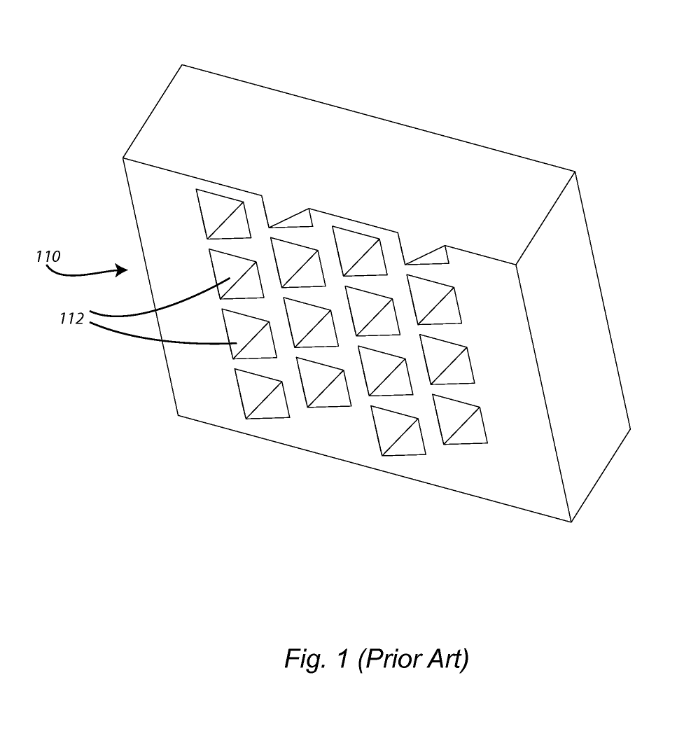

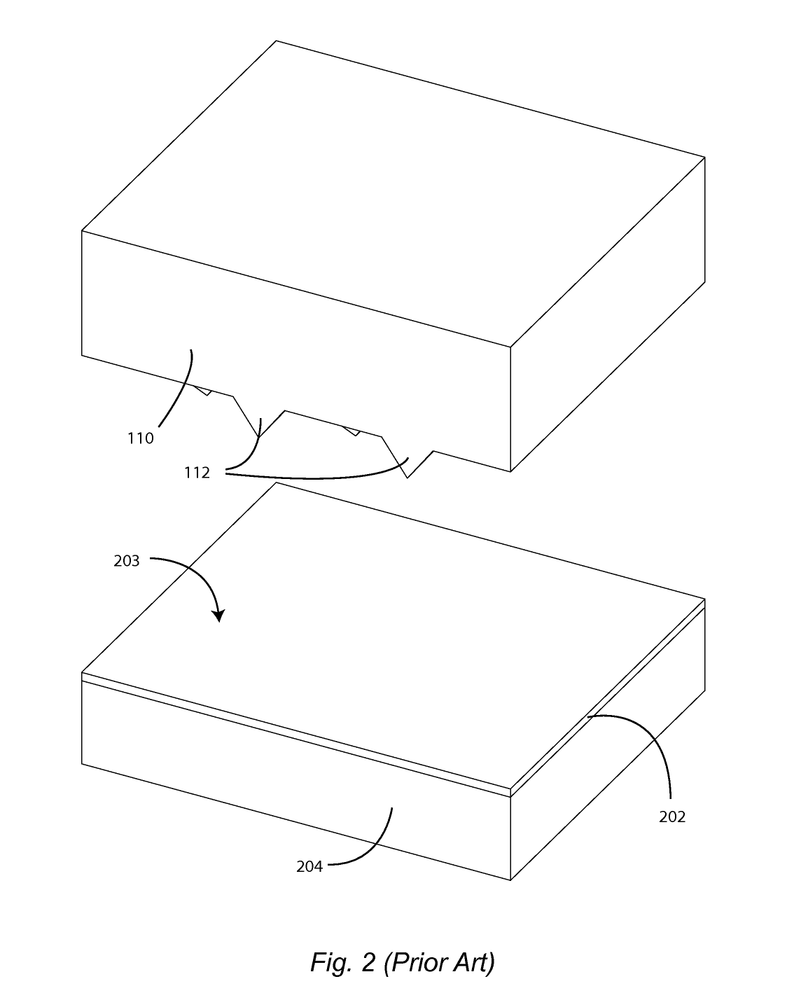

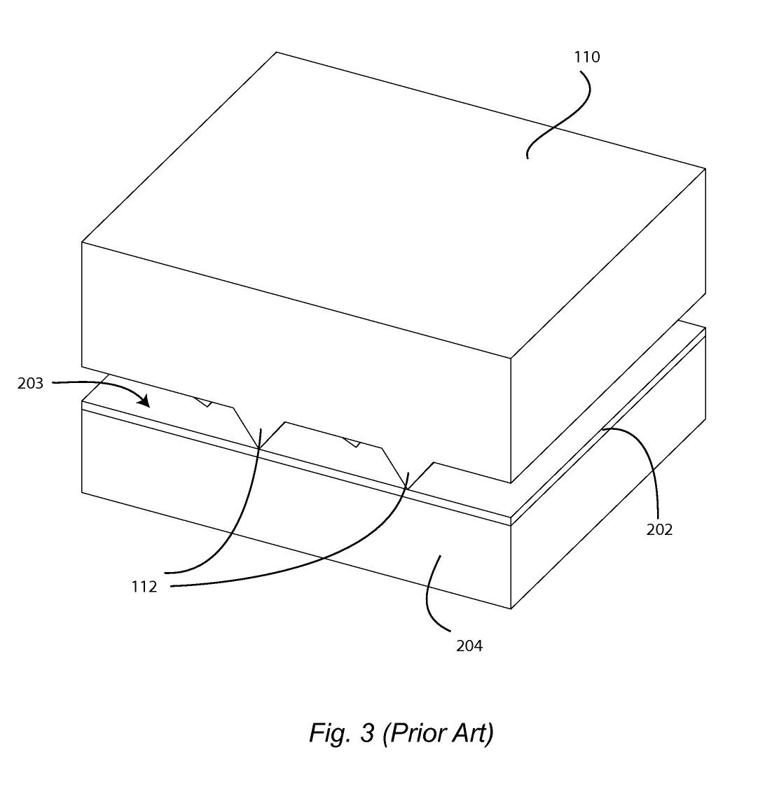

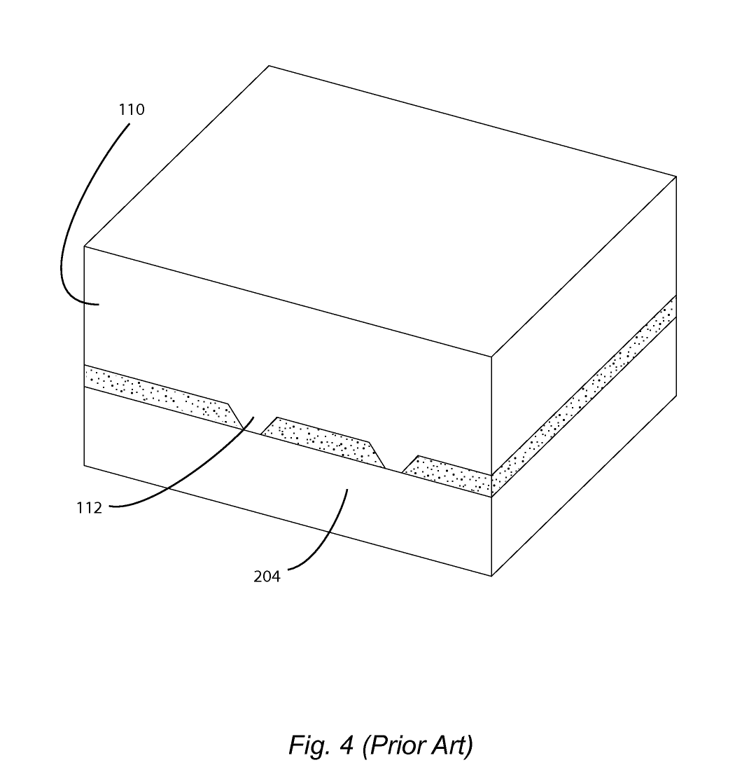

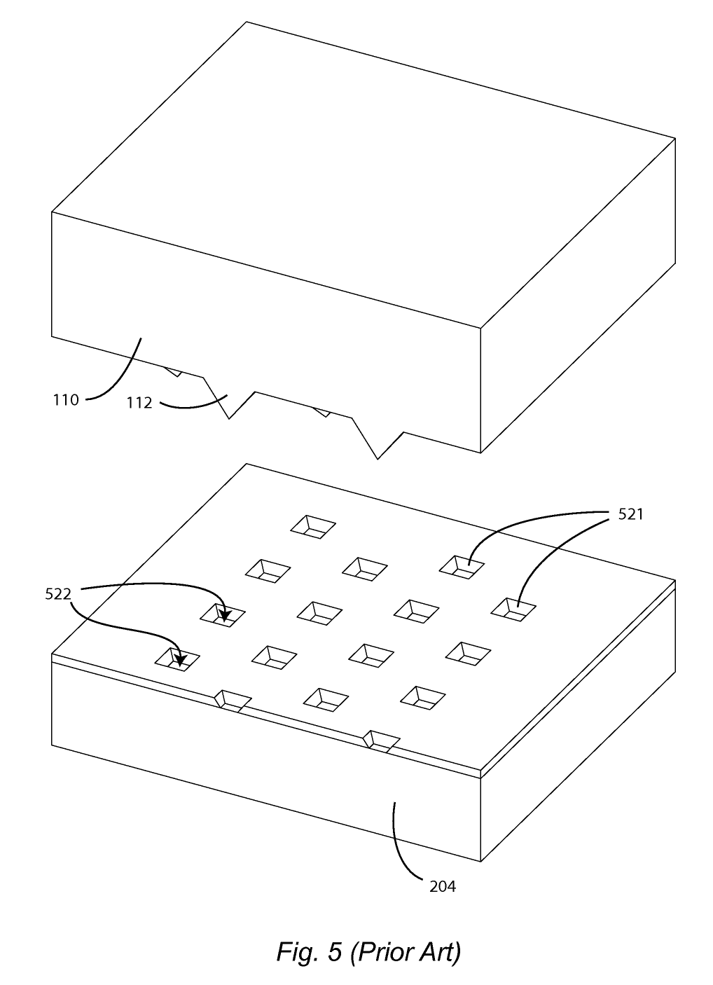

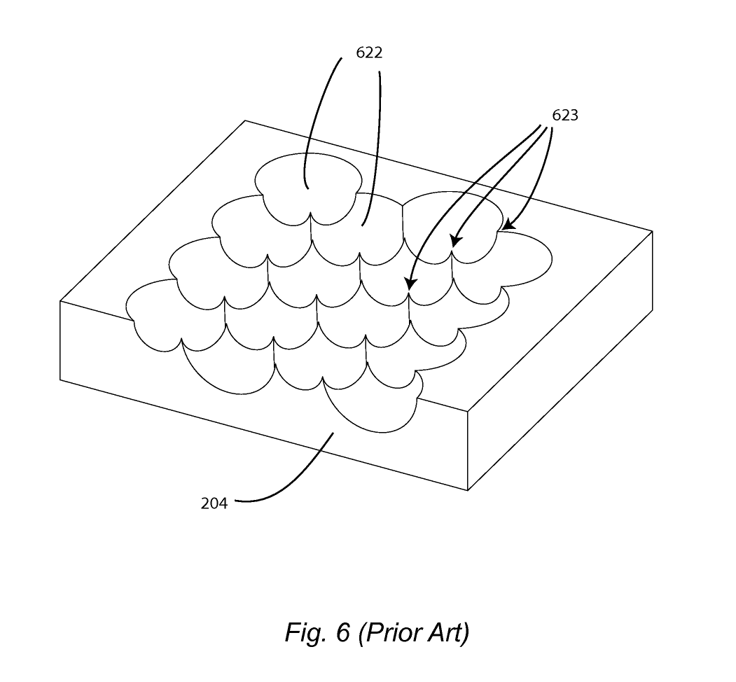

Briefly, using wedge imprint technology as shown with reference to FIGS. 1, 2, 3, 4, 5 and 6, the substrates are made by impressing protrusions 112 of a flexible stamp 110, upon a thin layer 202 of etch resist material, which covers a substrate wafer 204. The stamp tool used is of a material (typically elastomeric) that is soft enough so that the tool deforms upon contact with the substrate or wafer 204 upon which a coating of resist 202 has been previously applied. FIG. 3 shows the protrusions 112 of the stamp 110 just contacting the surface 203 of etch resist 202. The resist becomes soft upon heating and moves away from the locations of impression at the protrusions 112 under conditions of heat and pressure, revealing regions of the substrate adjacent to the protrusion. The resist can be heated before or after the stamp contacts the resist, or both before and after, and even while the stamp contacts the resist. The substrate is then cooled with the stamp 110 in place, and the stamp is removed, as shown at FIG. 5, leaving regions 522 of the substrate exposed under holes 521, from where the resist has been moved away. The substrate is further subjected to some shaping process, typically an etching process. Exposed portions 522 of the substrate are removed by an action, such as etching, and portions of the substrate that are protected by the resist, remain, as shown in FIG. 6 at 622 (etched away) and 623 (un-etched, or less etched) respectively. Pits (or cavities) 622 are sometimes referred to herein as having a hemispherical surface. The holes may be of any shape, including round and are not restricted to the square holes shown in FIG. 5.

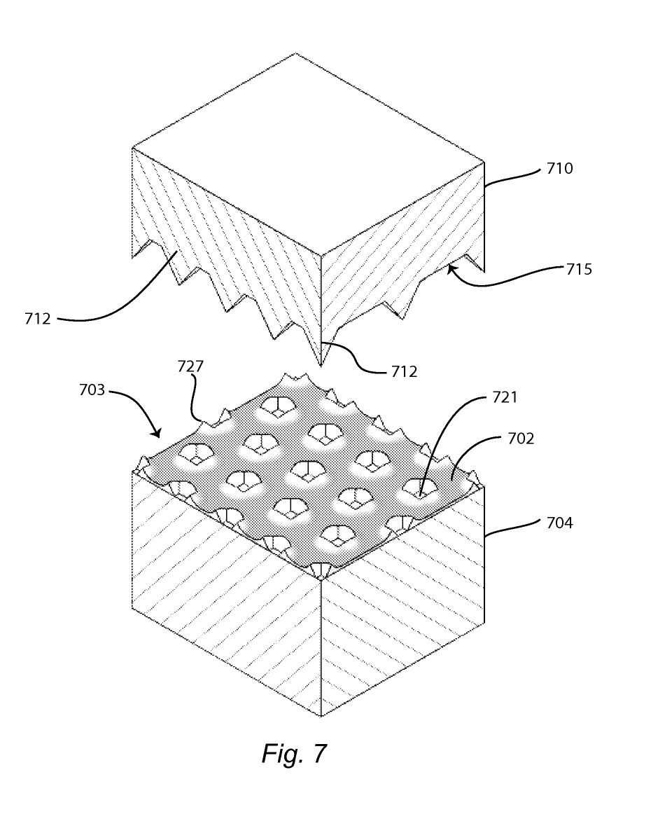

In some cases, described in the Gap application, it is beneficial to leave a gap between the surface 703 of the resist layer 702 and the underside 715 of the stamp 710, when the protrusions 712 are compressed to their fullest extent. FIG. 7 shows a stamp 710 withdrawn from the substrate 704 after wedging in such a case. FIG. 7 also shows the patterned resist layer 702 with substantially square openings 721 through the resist and peaked borders 727 around the openings. In a subsequent step, as described above, the substrate 704 will be exposed to etchant, which will etch the exposed silicon. FIG. 7 also shows that adjacent the holes 721, the surface 702 of the resist layer 703 has raised portions 727, where the resist had been drawn up along the faces of the protrusions 712. The resist solidified in this partially raised configuration.

A typical substrate is silicon, and a typical resist material is a wax or a mixture of waxes and resins. The stamp may be used over and over again. The protrusions of the stamp may be discrete, spaced apart, such as the pyramidal elements 112 shown. Or, they may be extended, wedge shaped elements, such as shown in the wedging applications. Or, they may be a combination thereof, or any other suitable shape that can cause the resist material to move away from the original covering condition.

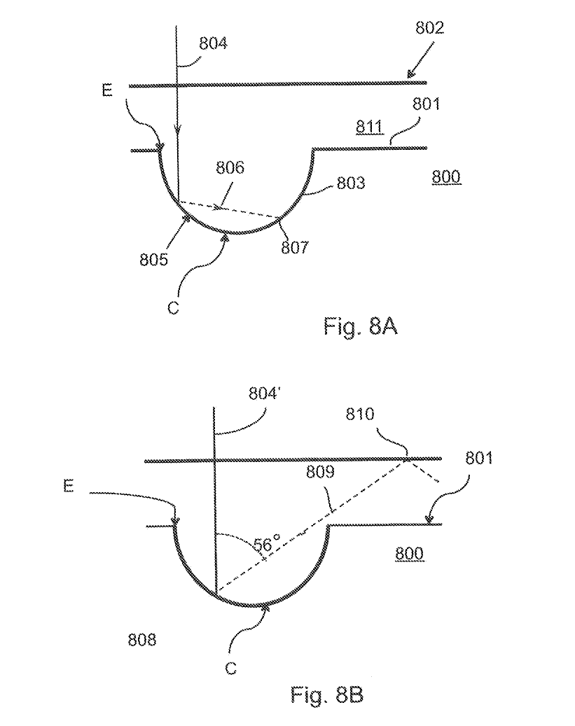

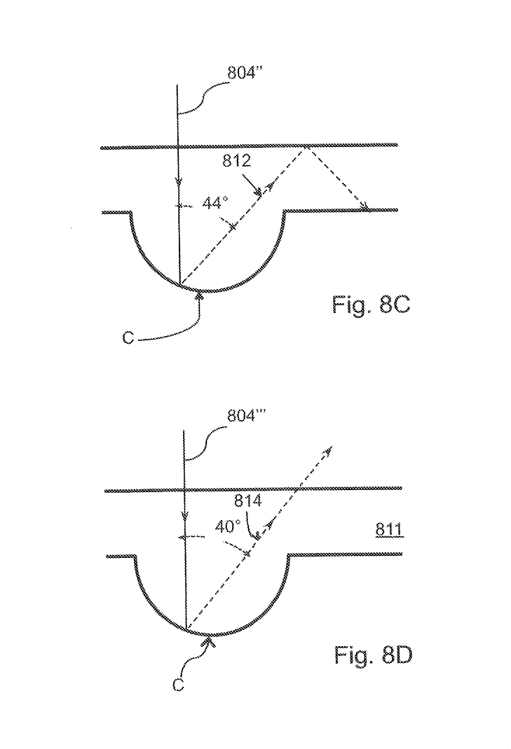

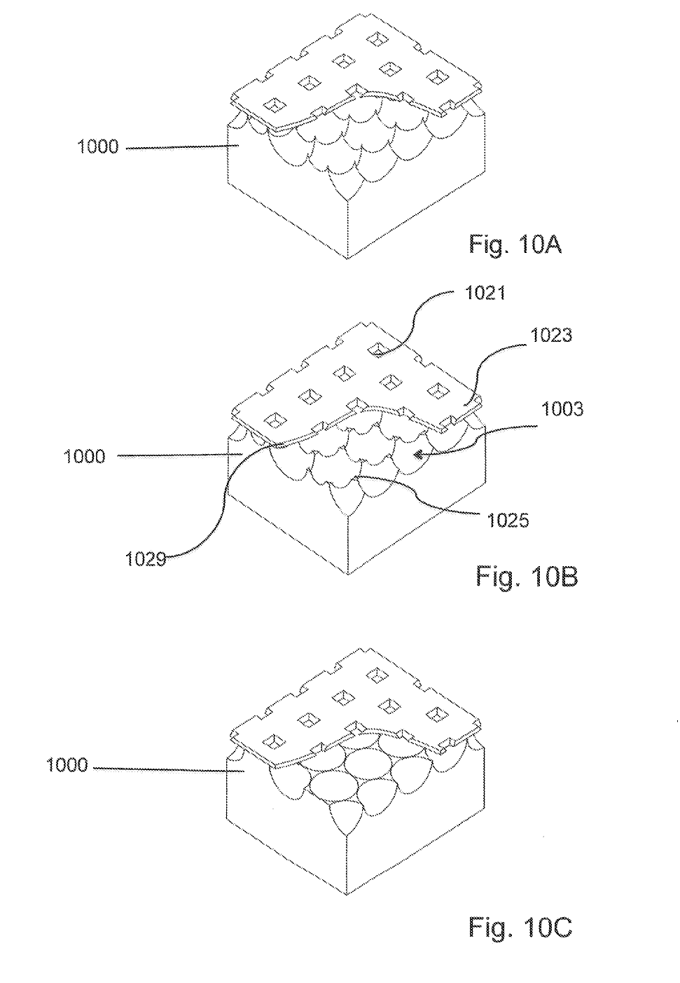

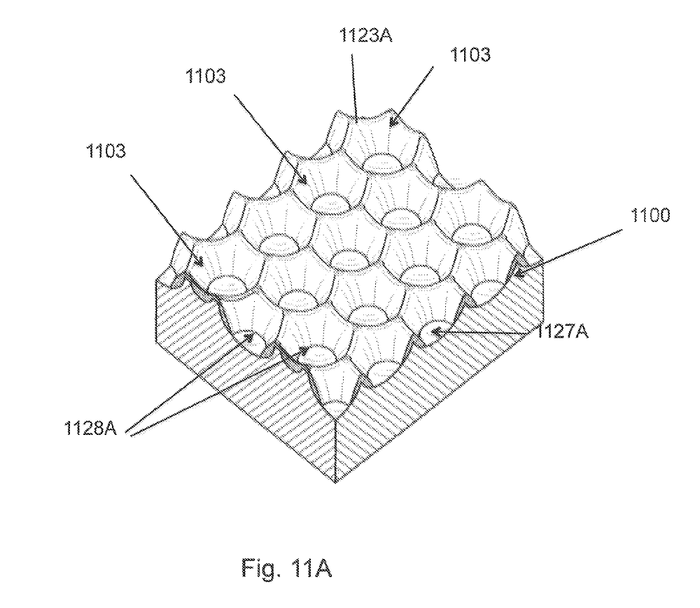

An isotropic etch is used to create the structure of any of FIGS. 10A, 10B, 10C, featuring cavity features, such as pits, or grooves, such as are discussed above. Discussion will be with reference to FIG. 10B, in which the degree of etch is between that which is associated with the structure shown in FIGS. 10A (relatively more etching) and 10C (relatively less etching) with approximately hemispherical pits 1003 in the wafer 1000 and with the resist mask 1023, which is in the form of a sheet with holes in it, supported at remaining roughly triangular small raised areas 1025 of contact with the wafer 1000. In some cases, such a degree of etching is most useful, while in others, more or less etching, as shown in FIG. 8A or 8C, respectively, would be more useful. It is important that there be enough silicon remaining after the etch to support the resist mask and so that the mask adheres or otherwise remains basically in place during subsequent operations, such as washing and the deformation steps discussed below. The resist projects (or overhangs) from these remaining relatively raised areas 1025 of contact over the newly etched cavity features, such as pits 1003. The resist is left in place after the etching process and the remaining etchant is removed from the resist-coated wafer, for example, by washing with DI water. The resist-coated wafer can then be dried, for example using warm dry air.

It should be noted that in reality, pits 1003 created by the wedging methods of the Wedging Patent are not strictly hemispherical. The features in FIGS. 6 and 10B are produced by exploiting the undercutting nature of the silicon etchant, known to those skilled in the art as an isotropic silicon etchant, as illustrated schematically in FIG. 10B, where the original silicon material is etched away from directly beneath the original location of the openings 1021 in the resist mask 1023, and then further, to locations that were originally covered by resist, so as to produce an undercut, with an overhang 1029 of resist. The openings 1021 are made through the resist in a honeycomb pattern, for instance at a 20 μm pitch. The resulting pattern in the silicon is shown in FIG. 6, and also in FIGS. 10A, 10B and 10C, for varying degrees of etching. In general, with normal variations in etching, the bottom of etched pits is not steep enough to provide effective light trapping and would benefit from additional topography.

For application to light trapping on silicon wafers, pit spacing may range from 2 to 40 microns with a preferred range of 5 to 20 microns. A standard sized wafer of 156 mm×156 mm would have approximately 140 million pits if the pits are arranged on a hexagonal array with a spacing of about 20 microns. Resist thickness can range from 0.5 to 5 microns, with a preferred range of from about 1 to about 3 microns. For other applications, the pit spacing and resist thickness may vary.

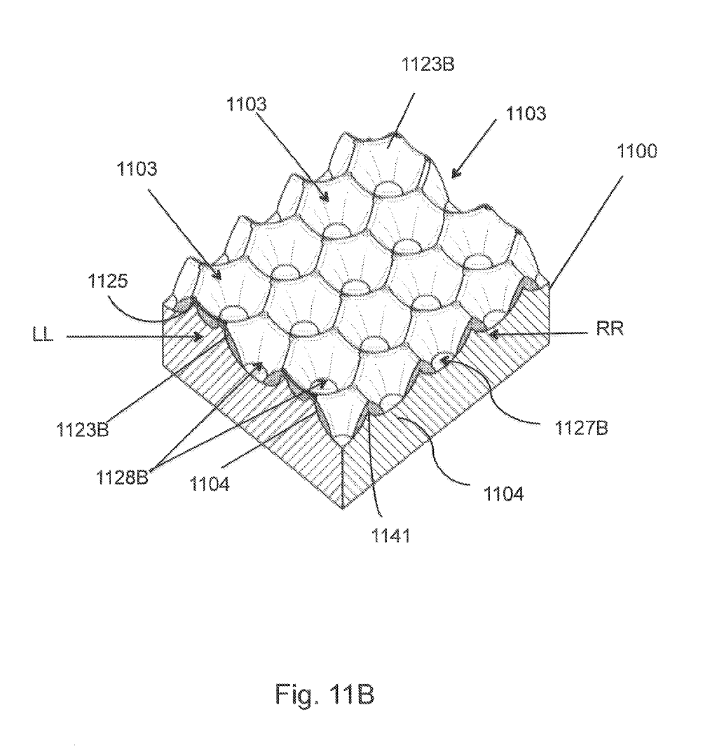

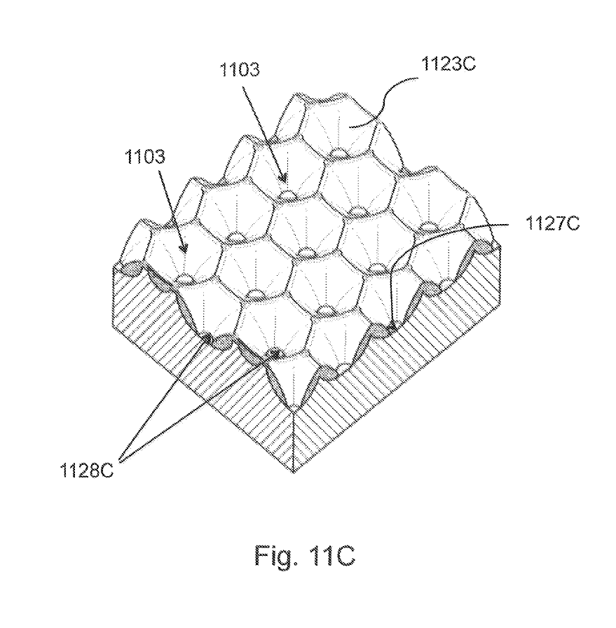

The wafer 1000 and the supported sheet 1023 of resist mask are then warmed to a mask deformation temperature, which is sufficient to soften the resist mask, but below the temperature at which the resist liquefies. The extent to which the resist softens and stretches, with its margins migrating, can vary, depending on the deformation conditions, e.g., deformation time and temperature as shown schematically in FIGS. 11A, 11B and 11C. For a typical resist composed of a mixture of resins and rosins, with a melting temperate between 75 C and 90 C, a typical temperature for resist deformation is 50 C and a typical duration is 30 seconds.

After a period of time at the deformation temperature, the resist 1023 deforms so as to conform to the outer portions of the etched pits 1003, but to leave the center C of the pit uncovered. As shown in FIGS. 11A, 11B and 11C, The size of the opening 1127A, 1127B and 1127C remaining in the center C of the pits 1103 depends on the length of time that the resist mask is kept at the deformation temperature, with longer time resulting in smaller open, uncoated regions 1127C, as shown in FIG. 11C, due to continued stretching of the deformed resist mask 1123C and migration of the margins of the resist along the surface of the pit 1103. By margins, it is meant the portions of the resist mask that constitute the perimeters 1128A, 1128B, and 1128C of the openings 1127A, 1127B and 1127C. Shorter time results in larger open, uncoated regions 1127A, as shown in FIG. 11A, because the deformed resist 1123A has had less time to migrate along the surface of the pit 1103.

It should be noted that the originally planar mask (for instance as shown at 1023 in FIG. 10B) has deformed considerably so as to drape down to and conform to the underlying hemispherical pit, as shown at 1123B in FIG. 11B. The mechanisms of deformation include bending as well as stretching and compression in various locations. The pattern of deformation is further complicated by the fact that the pits are approximate hemispheres with scallops, sharp ridges and areas with flat tops, as shown in FIG. 10B. The nature of this deformation can be understood by reference to cross-section faces LL and RR, which are part of FIG. 11B, for example. In these cross sections, the resist mask 1123B appears with stippling, while the underlying wafer 1104 appears with diagonal hatch marks. It should be noted that FIG. 11B is meant to be representative only and illustrative of the deformation of the mask. For example, the thickness of resist mask 1123B over the tops 1125 and ridges 1141 of the wafer 1104 may be thinner and even substantially thinner than shown in FIG. 11B.

Discussion will refer to FIG. 11B, in which the degree of softening and subsequent migration of the resist mask margins is moderate-between that which is associated with the structure shown in FIGS. 11A (relatively less migration) and 11C (relatively more migration).

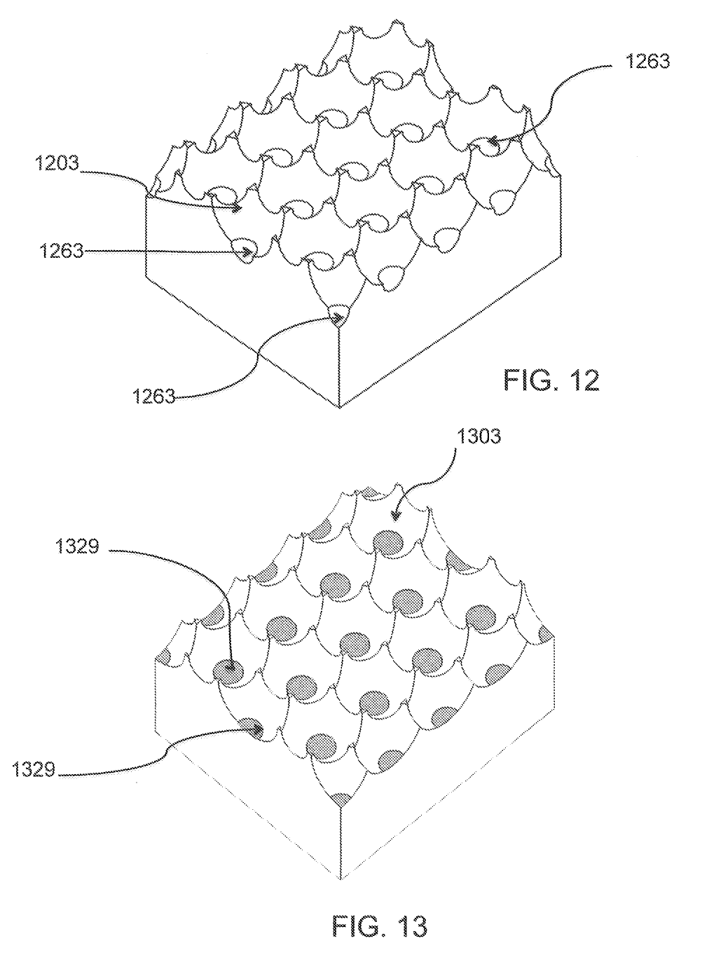

The wafer can then be exposed to another (auxiliary) bath of etchant, which attacks at the exposed area 1127B at the bottom of the pit 1103. The result is shown schematically with reference to FIG. 12, showing a secondary and smaller pit 1263 at the bottom of the original pit 1203 found in the first etch operation. FIG. 12 shows this compound pit structure. The second etchant bath can be the same or different from that used in the first etching process.

The secondary pit 1263 makes the light trapping feature deeper and it also increases the curvature at the base of the pit 1203, both of which lead to improved light trapping. It is also possible to repeat the resist deformation and etching again, resulting in a shape with a pit within a pit within a pit, or even again and again for many nested sets of pits, if the original pits are large enough and process controls are fine enough.

A suitable second etch to form a compound pit is known to those skilled in the art as an isotropic silicon etchant, comprised of hydrofluoric acid and nitric acid in addition to also potentially containing water and/or additional additives. A preferred hydrofluoric acid concentration is 0.5 to 7.5 M and a preferred nitric acid concentration is 2.1 to 7.9 M. A more preferred hydrofluoric acid concentration is 0.55 to 5.9 M and a more preferred nitric acid concentration is 4.1 to 5.6 M. Suitable etch times can range from 15 to 210 seconds. More complex shapes can be produced as follows: perform the resist softening and stretching with margin migration followed by a second etch as described here, followed by a second resist mask softening and a third etch of similar formulation to the second etch.

Alternatively, as shown schematically with reference to FIG. 13, after the resist is deformed so as to leave only an opening 1127B at the bottom of the pit 1103 the bottom 1329 of the pits 1303 may be roughened, for example, using an etch that roughens the surface (as compared to an etching process that removes material from the pit surface). Roughening can be conducted with a silicon etch containing hydrofluoric and nitric acids that is formulated to confer a micron-to-sub-micron texture to etched silicon by the appropriate choice of the ratio of the two acids, tending toward higher HF content. This can also be accomplished by using additives such as water and acetic acid as known in the art, as well as polymers.

It is also possible to deepen the pits and increase their curvature as shown with reference to FIG. 12 and also to roughen the surface 1329 of the deepened portion 1263 as shown at FIG. 13, for compound curvature, rough bottomed pits. This may be accomplished with a single etch that accomplishes all functions, or with successive etches.

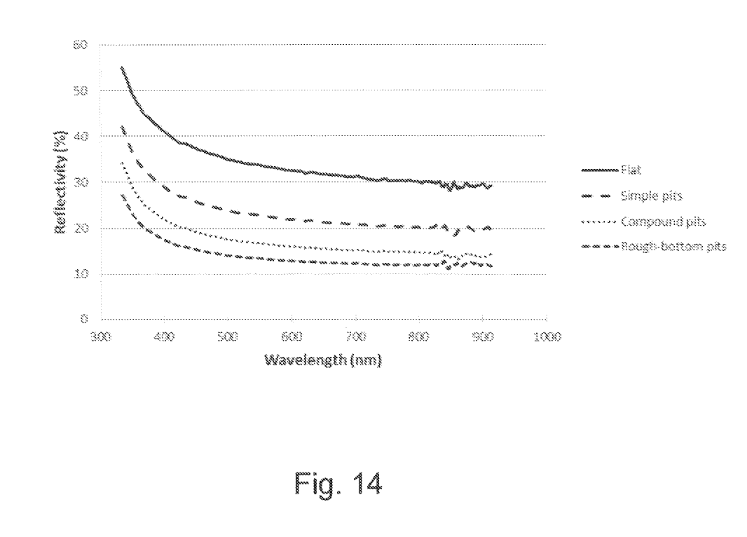

FIG. 14 shows, graphically, reflection data obtained on a spectrophotometer, as a function of wavelength for four different wafers. The flat sample is a reference, with no texture at al. The simple pits curve shows the lower reflection obtained with a surface of a field of hexagonally arranged hemispherical, simple pits. The compound pits curve shows the still lower reflection obtained with structure such as those shown in FIG. 12. The roughened bottom pits curve shows the yet lower reflectivity obtained with structure like that shown in FIG. 13. It will be recalled that lower reflectivity results in better performance.

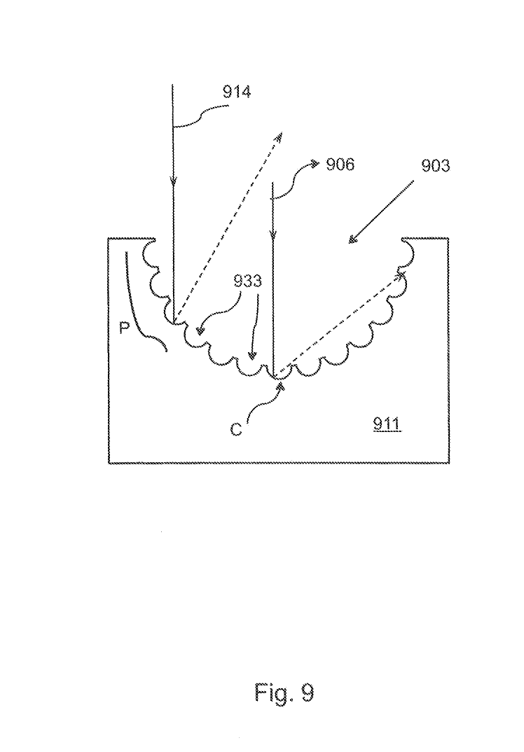

In general, it is beneficial to leave portions of a cavity or pit that are far from the center of the bottom of the pit with relatively smooth surface. It is not beneficial to roughen or change the topography or the surface other than near to the center. A reason can be understood with reference to FIG. 9, showing schematically a cross-section through a hemispherical pit 903, which has a finer topography of hemispherical pits 933 applied to the entire surface of the larger pit 903. The smaller pits help to produce a relatively larger angle of reflection tremendously near the bottom C of the pit. Ray 906 is reflected in such a way as to create a second impact with the wafer 911. However, the small pits 933 at the peripheral area P of the larger, enveloping pit 903, actually make matters worse. For example, ray 914 is reflected back out of the pit 903 without making a second impact on the wafer 911 within the larger pit 903, and it reaches the surface of the glass (not shown) at an angle too close to normal to allow for total internal reflection. Had the texture been as shown in FIG. 8A, this ray could have experienced a second absorption.

In another embodiment, material may be selectively deposited at the base of the pit in the area left exposed by the resist. Such deposited material may be deposited either by immersion in a solution or by other coating techniques known in the art. For example, the deposition of submicron structures—which may be particles, wires, or tubes can be achieved through solvent- or vapor-based techniques. The use of silver, gold, or platinum particles or wires, for example, may confer plasmonic light-trapping ability to the pit bottoms. Selective deposition of material may have also have uses other than the promotion of light trapping.

The desired size of opening in the resist at the bottom of the pit may be achieved by careful control of the temperature and duration to which the resist-coated wafer is exposed. If a larger hole is desired, a lower temperature or shorter duration or both may be used. If a smaller hole is desired, a higher temperature or longer duration or both may be used, thereby allowing the resist to migrate further along the walls of the pit. To control the hole size, precise control over the time and especially the temperature used to deform the resist is beneficial. Control of the temperature may be attained by methods known in the art, including but not limited to: contact to a hot plate, heating by infrared light, heating by contacting the back of the wafer to a bath of water or other liquid, and heating by the convective flow of warm air. Resists composed of a mixture of resins and rosins have the desired thermal properties for such resist deformation.

It has been noticed that the shapes of the holes changes as the mask deforms, in part by stretching. In the first instance, the lineal measurement of the perimeter of the holes increases, as can be seen by comparing the shape (square) and size of the holes 1021 in FIG. 10A with the shape (circular) and size of the opening regions 1127A (larger) in FIG. 11A. These figures are not to scale, but they do give a sense of the changes. The ultimate size of the openings depends on how long and at what temperature the mask is permitted to deform. It is interesting to note that the holes start as shown in FIG. 10B, and then stretch and enlarge to be as shown in FIG. 11A, for instance at 1127A, but then, if the mask is permitted to deform and migrate further, the holes become smaller, as shown at 1127B, and smaller, as shown at 1127C in FIG. 11C. It is even possible for them to close entirely (not shown).

Upon softening and deformation, the resist mask may usefully adhere to the wall of the pit. In certain embodiments, the overhanging resist conformally coats the wall of the pit or cavity. However, useful masking may be realized even without adherence of the resist to the wall.

It has been found that the deformation and stretching of the resist mask and migration of it's margins can take place with the wafer in any orientation relative to gravity—resist mask facing upward, downward, or at any angle with respect to gravity. This means that gravity is not the major driving force of the deformation and stretching. The orientation can be kept constant, or may be altered as the softening, stretching and margin migration takes place. Such insensitivity to orientation permits great flexibility in designing aspects of the processing equipment and method steps.

It may not be necessary to have a separate step in which any rinse water on the mask and in the space between mask and pit surface is dried off prior to the mask deformation step. In some cases, drying can take place as the resist-coated wafer is heated up to temperature at which deformation takes place.

Alternatively to thermal softening, the mask resist may be softened chemically, for example, by exposure to solvent vapor, and the deformation can take place without an elevation of temperature. Such a technique can be used on mask material that does not soften by thermal treatment. It is also possible to use a combination of thermal and chemical softening.

The textures etched in the wafer before the resist mask deformation step can be of different sizes and shapes from each other as determined by the size and shapes of the holes made in the resist mask. For example, the resist mask might be provided with a field of holes of a first size, on a hexagonal spacing in one region of the wafer, and significantly larger holes in other regions. For example, in the region of the hexagonal array, the holes might be squares with widths of 3 microns and on 15 micron spacing, while elsewhere on the wafer, there might be much larger square holes, for instance, 30 microns in width. In such a case, it is possible to perform the resist mask deformation in such a way that there are holes in the resist mask remaining in the bottom of the pits. In the region of the larger openings, after deformation, the resist will only cover small portion of the topography around the perimeter of the relatively much larger holes, leaving most of it open to subsequent steps. However, it is also possible to perform the deformation step at a higher temperature, or for a longer time, so that the bottom of the relatively smaller pits in the first region are completely covered, while the majority of the topography in the region with the much larger features remains uncovered. In this way, the larger features may be selectively treated in subsequent steps while the smaller features are masked either partially, or in their entirety, from the subsequent treatment steps.

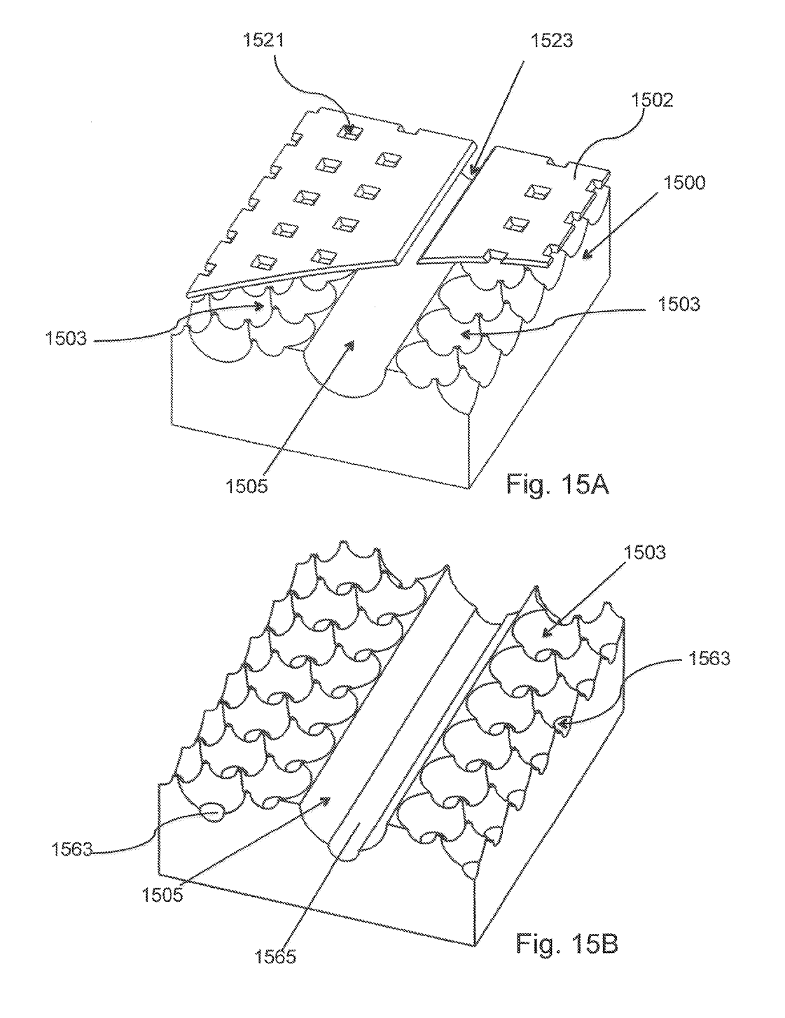

A second example using cavities of different shapes and sizes is illustrated in FIG. 15A, where the resist openings in the hexagonal array of pits are smaller than those in the one-dimensional trench. Suitably tuned resist softening and stretching conditions may be used to seal the resist in the hexagonal array of pits only, while leaving the trench bottoms exposed. This might be of use, for example, to selectively roughen the bottoms of the trenches so as to enhance the electrical contact between the metallization that will be deposited in the trenches and the wafer. Alternatively, such selective roughening can play a role in increasing the capillary traction along the length of the groove according to methods of the Self Aligned Cell technology and the SAC patent and application, discussed above.

A related method may also be used to selectively treat features that have only slightly different sizes. For example, the pits of one field of hexagonal pits may be deliberately made slightly larger than the pits of another field. The field of smaller pits can be completely sealed against subsequent processing, by conducting the step of softening the resist and letting it migrate only until the smaller of the holes are completely covered, but not the larger of the holes. A field may consist of an arrangement of smaller and larger pits in a designed arrangement, and again, the smaller pits may be selectively sealed.

The upper surface of the resist layer, prior to the deformation step, can look substantially planar as shown in FIG. 10B. Alternatively, as shown at FIG. 7, the upper surface 702 of the resist layer 703 can be substantially non-planar as might be the case, depending on how the resist is patterned, as shown at the horns 727. Such non-planarities can arise in different modes of wedging operations, such as the gap leaving techniques disclosed in the gap technology and related gap patents, referenced above.

FIG. 15A shows, schematically, a wafer 1500, in which a hexagonal field of pits 1503 has been created, as described above, as well as a groove 1505. A linear opening 1523 in the resist mask 1502, causes a groove 1505 of generally semi-cylindrical shape to be etched. Such groove-like features may be created simultaneously with other types of features, such as the pits. The radius of the grooves 1505 can be made to be the same as the radius of the pits 1503, smaller or larger, depending on the relative size of the openings 1521 and 1523 used to etch the pits and the grooves, respectively. In FIG. 15A, the radius of the groove 1505 is larger than the radius of the pits 1503.

The layer of resist 1502 can be softened and relaxed, as discussed above, to form a secondary resist mask, that covers the outer portions of the pits, as discussed, and also corresponding portions of the groove 1505. The secondary resist mask self aligns where it is desired to be, because it is already near to the desired position, but just needs to soften and deform into it. As shown schematically with reference to FIG. 15B, subsequent etching step can then be applied, to form compound pits 1563 and a groove 1505 that also has a compound curvature 1565 at its bottom surface, directly analogous to that with the pits, discussed above. Alternatively, or in addition, the bottom surface of the groove 1505 can be roughened, as discussed above in connection with the roughened bottom pits. Also, or alternatively, rather than etching and/or roughening, another material can be deposited into the bottoms of the grooves, through openings in the softened and relaxed layer of resist, as discussed above in connection with the pits. Any combinations of compound pits and grooves, roughened bottom features of either sort, and also additional treatments of any sort, can be practiced.

The texture could also consist of a field of grooves. The grooves could also be discontinuous—that is the linear opening could be discontinuous (dotted line), resulting in a discontinuous semi-cylindrical groove.

The foregoing discussion focuses on surface cavities that have been formed by isotropic etching, which, in silicon, tend to be substantially hemispherical. The inventions disclosed herein are not limited to use following an isotropic etch. They can be used to enhance by deepening, or roughening, cavities that have been formed by any sort of etch. What is important is that there be a mask in place, with overhanging portions, which mask can be deformed in place, and used again to mask a slightly different region of the already treated substrate.

More generally, although foregoing discussion focuses on surface cavities that have been formed by etching in silicon, the inventions disclosed herein are not limited to use with silicon, or even with conventional etching. They can be used to enhance by deepening, or roughening, cavities that have been formed by any sort of material removal process that also uses a mask, portions of which will be left overhanging regions of the formed cavities after the material removal step. What is important is that there be a mask in place, with overhanging portions, which mask can be deformed in place, and used again to mask a slightly different region of the already treated substrate. Thus, semiconductors other than silicon may be used. Materials other than semiconductors may also be used. The mask can be polymeric or other, and it may be such that can be softened and deformed with thermal treatment, chemical treatment, or both, or some other treatment.

This disclosure describes and discloses more than one invention. The inventions are set forth in the claims of this and related documents, not only as filed, but also as developed during prosecution of any patent application based on this disclosure. The inventors intend to claim all of the various inventions to the limits permitted by the prior art, as it is subsequently determined to be. No feature described herein is essential to each invention disclosed herein. Thus, the inventors intend that no features described herein, but not claimed in any particular claim of any patent based on this disclosure, should be incorporated into any such claim. Alternatively, in certain embodiments, it is contemplated that the independent features can be combined in order to enjoy the benefits and advantages of each feature.

For instance, the following different features are each potentially separate from each other, and can be used alone, or in combination with any single other one or any sub-combinations of the mentioned features: using a semiconductor substrate and treatment that etches away such a semiconductor, whether silicon, germanium, or any other semiconductor; isotropic etchant; non-isotropic etchant; etch resist mask that is thermally softenable; etch resist mask that is chemically softenable; increasing the depths of cavities; roughening the bottom surface of cavities; depositing material in the cavities; depositing a treating agent in the cavities; using cavities of the same shapes as each other; cavities of different shapes from each other; forming and treating within cavities of elongated, extended shapes, such as trenches; using cavities of discrete, spaced apart shapes, such as pits in a honeycomb or checkerboard pattern; allowing the mask to deform to an extent such that all of the cavities have the same size openings remaining after the mask is deformed; allowing the mask to deform to an extent such that some of the cavities have the different sized openings from each other remaining after the mask is deformed; adding material to the cavities through the self-aligned mask; and creating cavities within cavities, again and again as many times as needed.

Some assemblies of hardware, or groups of steps, are referred to herein as an invention. However, this is not an admission that any such assemblies or groups are necessarily patentably distinct inventions, particularly as contemplated by laws and regulations regarding the number of inventions that will be examined in one patent application, or unity of invention. It is intended to be a short way of saying an embodiment of an invention.

An abstract is submitted herewith. It is emphasized that this abstract is being provided to comply with the rule requiring an abstract that will allow examiners and other searchers to quickly ascertain the subject matter of the technical disclosure. It is submitted with the understanding that it will not be used to interpret or limit the scope or meaning of the claims, as promised by the Patent Office's rule.

The foregoing discussion should be understood as illustrative and should not be considered to be limiting in any sense. While the inventions have been particularly shown and described with references to preferred embodiments thereof, it will be understood by those skilled in the art that various changes in form and details may be made therein without departing from the spirit and scope of the inventions as defined by the claims.

The corresponding structures, materials, acts and equivalents of all means or step plus function elements in the claims below are intended to include any structure, material, or acts for performing the functions in combination with other claimed elements as specifically claimed.

### ASPECTS OF INVENTIONS

The following aspects of inventions hereof are intended to be described herein, and this section is to ensure that they are mentioned. They are styled as aspects, and although they appear similar to claims, they are not claims. However, at some point in the future, the applicants reserve the right to claim any and all of these aspects in this and any related applications.

A1. A method of patterning a surface of a substrate, comprising:
a. providing:
   i. a substrate comprising at least one surface cavity, and;
   ii. a patterned mask disposed over the surface, the mask comprising an opening adjacent the cavity, wherein the perimeter of the cavity is greater than the perimeter of the opening, the mask being positioned relative to the cavity such that an overhanging mask portion is spaced from a surface of the cavity;
b. deforming the overhanging mask portion into covering proximity with a portion of the surface of the cavity, wherein at least a region of the cavity surface remains exposed; and
c. providing to the surface, a treating agent, of a type and under conditions such that cavity surface portions covered by the mask resist treatment and the exposed region of the cavity becomes treated.

A2. The method of aspect A1, the surface comprising a semiconductor surface, further comprising, before the step of deforming the overhanging mask portion, the steps of:
a. providing a covering of mask material on the surface, which mask material is patterned so that at least one region of the surface is left exposed, and at least one region is covered with mask material;
b. providing an etchant to the surface; and
c. allowing the etchant to etch away semiconductor material at the exposed regions, thereby producing the at least one cavity.

A3. A method for providing a texture to a semiconductor surface, the method comprising the steps of:
a. providing a mask of material on the surface, which mask material is patterned so that some regions of the surface are covered with resist material, and a plurality of region are exposed;
b. providing an etchant to the surface;
c. allowing the etchant to etch away semiconductor material at the exposed regions, thereby producing a plurality of cavities in the surface, which cavities undercut the mask material, leaving overhanging portions of mask material;
d. deforming the overhanging mask portions into covering proximity with a portion of the surface of the plurality of cavities, wherein at least a region of each cavity surface remains exposed; and
e. providing, to the semiconductor surface a treating agent, of a type and under conditions such that, cavity surface portions covered by the mask resist treatment and the exposed regions of the cavities become treated.

A4. The method of aspect A1, the surface comprising a semiconductor surface.

A5. The method of any preceding aspect, the treating agent comprising an etchant.

A4. The method of any preceding aspect, whereby, cavity surface portions covered by the mask resist treatment and the exposed regions of the cavities become treated.

A5. The method of any preceding aspect, the treating agent adding material.

A6 The method of aspect A5, the material added comprising a sub-micron scale structure selected from the group consisting of: particles, wires and tubes.

A7. The method of aspect A6, the sub-micron scale structures comprising a material selected from the group consisting of: silver, gold and platinum.

A8. The method of any of aspects 2-7, whereby exposed regions of the plurality of cavities are treated and the portions of the surface to which the mask has deformed into covering proximity are not treated, without there being any step to insure the location of the covering portions of the mask.

A9. The method of aspect A5, the etchant causing the exposed regions of the cavities to deepen.

A10. The method of aspect A5, the etchant causing exposed regions of the bottom surfaces of the cavities to roughen.

A11. The method of aspect A5, the cavities having a bottom surface curvature, the etchant causing the bottom exposed portions of the cavities to be reshaped to have a bottom surface curvature with a radius of curvature that is smaller than the radius of the bottom surface curvature before the step of exposing the surface to an etchant.

A12. The method of any preceding aspect, the step of deforming the overhanging mask portion comprising thermally treating the mask such that it softens and moves toward a surface of a respective cavity.

A13. The method of any preceding aspect, the step of deforming the overhanging mask portion comprising chemically treating the mask such that it softens and moves toward a surface of a respective cavity.

A14. The method of any preceding aspect, the cavities having been formed in the surface with a first etchant, the treating agent comprising an etchant of the same chemical composition as the first etchant.

A15. The method of any preceding aspect, the cavities having been formed in the surface with a first etchant, the treating agent comprising an etchant of a different chemical composition from the first etchant.

A16. The method of any preceding aspect, the step of deforming the overhanging mask portion comprising treating the mask such that it softens and moves toward a surface of a respective cavity and then remains stationary.

A17 The method of any preceding aspect, the step of deforming the overhanging mask portion comprising treating the mask such that it softens and moves toward a surface of a respective cavity and adheres to the surface cavity.

A18. The method of any preceding aspect, the step of deforming the overhanging mask portion comprising treating the mask such that it softens and moves toward a surface of a respective cavity and then continues to move with respect to the cavity surface.

A19 The method of aspect A18, wherein as the mask continues to move, it stretches.

A20. The method of aspect A18, wherein the mask continues to move so that substantially the entire cavity surface is covered with mask.

A21. The method of any preceding aspect, the semiconductor comprising silicon.

A22. The method of aspect A21, the etchant comprising an substantially isotropic etchant.

A23. The method of any of aspects 2-22, the plurality of cavities comprising spaced apart cavities that undercut the mask material adjacent the exposed regions, leaving mask material that is supported by regions of the surface that have not been etched away.

A24. The method of aspect A23, the pattern comprising a hexagonal distribution.

A25. The method of aspect A23, the pattern comprising extended grooves.

A26. The method of aspect A24, the pattern also comprising extended grooves.

A27. The method of aspect A23, the pattern comprising at least two different shapes of cavities.

A28. The method of aspect A23, the etchant provided to the surface comprising an isotropic etchant.

A29. The method of aspect A28, the treating agent comprising an isotropic etchant.

A30. The method of aspect A28, the treating agent and the isotropic etchant having different compositions from each other.

A31. The method of aspect A28, the treating agent and the isotropic etchant having substantially the same compositions as each other.

A32. The method of any of aspects 2-31, the at least one cavity comprising at least two cavities, one cavity having a larger perimeter than the other, the patterned mask comprising openings adjacent each of the cavities, wherein the perimeters of the cavities are larger than the perimeters of the respective adjacent openings of the mask, the step of deforming the mask comprising deforming the mask under conditions and for a duration of time such that the overhanging mask portions deform into conforming proximity with the cavities such that the surfaces of the cavity with the relatively smaller perimeter become substantially completely covered with the mask while at least some of the surface of the cavity with the relatively larger perimeter remains exposed.

A33. The method of aspect A32, the cavity having the larger perimeter having a perimeter that is at least ten times larger than that of the cavity having the smaller perimeter.

A34. A solar cell with a semiconductor wafer having a surface, the surface comprising spaced apart cavities, at least some of the cavities having a bottom surface that has a first region with a first radius of curvature, and also within the same cavity, a second region having a second, smaller radius of curvature.

A35. The solar cell of aspect A34, the second region being located deeper within the cavity than the first region.

A36. The solar cell of aspect A34, at least some of the cavities having a bottom surface that has a first region with a first radius of curvature, and also within the same cavity, a second region having a second, smaller radius of curvature, and also within the same feature, a third region having a third radius of curvature, smaller than that of the second region.

A37. A solar cell comprising a semiconductor wafer with a surface, the surface comprising spaced apart cavities, at least some of the cavities having a bottom surface that has a region with a first degree of roughness, and also within the same cavity, a region of a different, lesser degree of roughness.

A38. The solar cell of aspect A37, the cavities having walls, the walls have a different degree of roughness than that of the bottom surface.

A39. The solar cell of any of aspects A34-A38, the semiconductor comprising silicon.

Having described the inventions, what is claimed is:

1. A method for providing a texture to a semiconductor surface, the method comprising the steps of:
a. providing a mask of material on the surface, which mask material is patterned so that some regions of the surface are covered with resist material, and a plurality of region are exposed;
b. providing an etchant to the surface;
c. allowing the etchant to etch away semiconductor material at the exposed regions, thereby producing a plurality of cavities in the surface, which cavities undercut the mask material, leaving overhanging portions of mask material;
d. deforming the overhanging mask portions into covering proximity with a portion of the surface of the plurality of cavities, wherein at least a region of each cavity surface remains exposed; and
e. providing, to the semiconductor surface a treating agent, of a type and under conditions such that, cavity surface portions covered by the mask resist treatment and the exposed regions of the cavities become treated.

2. The method of claim 1, the treating agent comprising an etchant.

3. The method of claim 1, the treating agent adding material.

4. The method of claim 1, whereby exposed regions of the plurality of cavities are treated and the portions of the surface to which the mask has deformed into covering proximity are not treated, without there being any step to insure the location of the covering portions of the mask.

5. The method of claim 2, the etchant causing the exposed regions of the cavities to deepen.

6. The method of claim 2, the etchant causing exposed regions of the bottom surfaces of the cavities to roughen.

7. The method of claim 2, the cavities having a bottom surface curvature, the etchant causing the bottom exposed portions of the cavities to be reshaped to have a bottom surface curvature with a radius of curvature that is smaller than the radius of the bottom surface curvature before the step of exposing the surface to an etchant.

8. The method of claim 1, the step of deforming the overhanging mask portion comprising thermally treating the mask such that it softens and moves toward a surface of a respective cavity.

9. The method of claim 1, the step of deforming the overhanging mask portion comprising chemically treating the mask such that it softens and moves toward a surface of a respective cavity.

10. The method of claim 1, the cavities having been formed in the surface with a first etchant, the treating agent comprising an etchant of the same chemical composition as the first etchant.

11. The method of claim 1, the cavities having been formed in the surface with a first etchant, the treating agent comprising an etchant of a different chemical composition from the first etchant.

12. The method of claim 1, the step of deforming the overhanging mask portion comprising treating the mask such that it softens and moves toward a surface of a respective cavity and then remains stationary.

13. The method of claim 1, the step of deforming the overhanging mask portion comprising treating the mask such that it softens and moves toward a surface of a respective cavity and adheres to the surface cavity.

14. The method of claim 1, the step of deforming the overhanging mask portion comprising treating the mask such that it softens and moves toward a surface of a respective cavity and then continues to move with respect to the cavity surface.

15. The method of claim 14, wherein the mask continues to move so that substantially the entire cavity surface is covered with mask.

16. The method of claim 1, the semiconductor comprising silicon.

17. The method of claim 6, the etchant comprising an substantially isotropic etchant.

18. The method of claim 1, the plurality of cavities comprising spaced apart cavities that undercut the mask material adjacent the exposed regions, leaving mask material that is supported by regions of the surface that have not been etched away.

19. The method of claim 18, the pattern comprising a hexagonal distribution.

20. The method of claim 18, the pattern comprising extended grooves.

21. The method of claim 19, the pattern also comprising extended grooves.

22. The method of claim 18, the pattern comprising at least two different shapes of cavities.

23. The method of claim 18, the etchant provided to the surface comprising an isotropic etchant.

24. The method of claim 23, the treating agent comprising an isotropic etchant.

25. The method of claim 23, the treating agent and the isotropic etchant having different compositions from each other.

26. The method of claim 23, the treating agent and the isotropic etchant having substantially the same compositions as each other.

27. A method of patterning a surface of a substrate, comprising:
a. providing:
i. a substrate comprising at least one surface cavity, and;
ii. a patterned mask disposed over the surface, the mask comprising an opening facing the cavity, wherein the perimeter of the cavity is greater than the perimeter of the opening, the mask being positioned relative to the cavity such that an overhanging mask portion is spaced from a surface of the cavity;
b. deforming the overhanging mask portion into covering proximity with a portion of the surface of the cavity, wherein at least a region of the cavity surface remains exposed; and
c. providing to the surface, a treating agent, of a type and under conditions such that cavity surface portions covered by the mask resist treatment and the exposed region of the cavity becomes treated.

28. The method of claim 27, the surface comprising a semiconductor surface, further comprising, before the step of deforming the overhanging mask portion, the steps of:
a. providing a covering of mask material on the surface, which mask material is patterned so that at least one region of the surface is left exposed, and at least one region is covered with mask material;
b. providing an etchant to the surface; and
c. allowing the etchant to etch away semiconductor material at the exposed regions, thereby producing the at least one cavity.

29. A solar cell with a semiconductor wafer having a surface, the surface comprising spaced apart cavities, at least some of the cavities having a bottom surface that has a first region with a first radius of curvature, and also within the same cavity, a second region having a second, smaller radius of curvature.

30. The solar cell of claim 29, the second region being located deeper within the cavity than the first region.

31. The solar cell of claim 29, at least some of the cavities having a bottom surface that has a first region with a first radius of curvature, and also within the same cavity, a second region having a second, smaller radius of curvature, and also within the same feature, a third region having a third radius of curvature, smaller than that of the second region.

32. A solar cell comprising a semiconductor wafer with a surface, the surface comprising spaced apart cavities, at least some of the cavities having a bottom surface that has a region with a first degree of roughness, and also within the same cavity, a region of a different, lesser degree of roughness.

33. The solar cell of claim 32, the cavities having walls, the walls have a different degree of roughness than that of the bottom surface.

34. The solar cell of claim 29, the semiconductor comprising silicon.
